(19) United States
(12) Patent Application Publication
(10) Pub. No.: US 2022/0407289 A1
(43) Pub. Date: Dec. 22, 2022

(54) OPTICAL ASSEMBLY WITH A VERTICAL CAVITY SURFACE EMITTING LASER DEVICE DISPOSED ON AN INTEGRATED CIRCUIT DRIVER CHIP

(71) Applicant: Lumentum Operations LLC, San Jose, CA (US)

(72) Inventors: Wei SHI, San Jose, CA (US); Hao HUANG, San Jose, CA (US); Lijun ZHU, Dublin, CA (US); Siu Kwan CHEUNG, San Jose, CA (US); Kevin WANG, Fremont, CA (US); John Michael MILLER, Ottawa (CA)

(21) Appl. No.: 17/447,780

(22) Filed: Sep. 15, 2021

Related U.S. Application Data
(60) Provisional application No. 63/213,601, filed on Jun. 22, 2021.

(51) Int. Cl. H01S 5/026; H01S 5/0225; H01S 5/0233

(52) U.S. Cl. CPC H01S 5/0261; H01S 5/0225; H01S 5/0233; H01S 5/183

(57) ABSTRACT

An optical assembly includes a substrate; an optical subassembly that is disposed on a region of a surface of the substrate; a housing that is disposed on another region of the surface of the substrate; a first optical element that is disposed on a first support component of the housing; and a second optical element that is disposed on a second support component of the housing. The optical subassembly includes an integrated circuit (IC) driver chip; a redistribution layer (RDL) structure that is disposed on a surface of the IC driver chip, wherein the RDL structure includes a cavity; and a vertical cavity surface emitting laser (VCSEL) device disposed on a region of the surface of the RDL structure that is within the cavity of the RDL structure.

### RELATED APPLICATION

This application claims priority to U.S. Provisional Patent Application No. 63/213,601, for “MINIATURIZED PACKAGING OF 3D SENSING PROJECTOR WITH HIGH OPTICAL POWER,” filed on Jun. 22, 2021, the content of which is incorporated by reference herein in its entirety.

### TECHNICAL FIELD

The present disclosure relates generally to an optical assembly and to an optical subassembly of the optical assembly that includes a vertical cavity surface emitting laser (VCSEL) device disposed on an integrated circuit (IC) driver chip.

### BACKGROUND

Time-of-flight (ToF) systems, such as three-dimensional (3D) sensing systems, light detection and ranging (LIDAR) systems, and/or the like, emit optical pulses into a field of view, detect reflected optical pulses, and determine distances to objects in the field of view by measuring delays and/or differences between the emitted optical pulses and the reflected optical pulses.

### SUMMARY

In some implementations, an optical subassembly includes an IC driver chip; a redistribution layer (RDL) structure that is disposed on a surface of the IC driver chip, wherein the RDL structure includes a cavity; and a VCSEL device disposed on a region of the surface of the RDL structure that is within the cavity of the RDL structure.

In some implementations, an optical assembly includes a substrate; an optical subassembly that is disposed on a region of a surface of the substrate; a housing that is disposed on another region of the surface of the substrate; a first optical element that is disposed on a first support component of the housing; and a second optical element that is disposed on a second support component of the housing, wherein the optical subassembly includes: an IC driver chip, an RDL structure that is disposed on a surface of the IC driver chip, wherein the RDL structure includes a cavity, and a VCSEL device disposed on a region of the surface of the RDL structure that is within the cavity of the RDL structure.

In some implementations, an optical assembly includes a substrate; and an optical subassembly that is disposed on a region of a surface of the substrate, wherein the optical subassembly comprises: an IC driver chip, an RDL structure that is disposed on a surface of the IC driver chip, wherein the RDL structure includes a cavity, and a VCSEL device disposed on a region of the surface of the RDL structure that is within the cavity of the RDL structure.

### BRIEF DESCRIPTION OF THE DRAWINGS

FIG. 1 is a diagram of an example optical subassembly described herein.

FIGS. 2A-2D are diagrams of an example optical assembly described herein.

FIGS. 3A-3B are diagrams of another example optical assembly described herein.

### DETAILED DESCRIPTION

The following detailed description of example implementations refers to the accompanying drawings. The same reference numbers in different drawings may identify the same or similar elements.

A conventional projector module can be used for a three-dimensional (3D) sensing application, such as a time-of-flight (TOF) application. In some cases, the conventional projector module can be assembled using a conventional packaging process. For example, an IC driver chip, a VCSEL device, and a capacitor can be bonded onto a surface of a substrate by using solder reflow, and other components can be attached to the surface of the substrate by epoxy. However, the IC driver chip occupies a large region of the surface of the substrate, which increases a size of the substrate and therefore increases a size (e.g., an XY footprint) of the conventional projector module. This prevents the conventional projector module from being included in some user devices, such as smart phones.

Moreover, a conventional projector module includes a photodiode (PD) and a collimating lens. The PD can detect an in-field failure of the collimating lens (e.g., when the collimator lens is broken or has fallen off a housing of the conventional projector module). When the PD detects an in-field failure, the IC driver shuts down the VCSEL device of the conventional projector module (e.g., to prevent further emission of light by the VCSEL device for eye safety compliance). However, inclusion of the PD in the conventional projector module further increases the size (e.g., the XY footprint) of the conventional projector module.

Further, a typical substrate used in a conventional projector module includes multiple dielectric layers, which impede a thermal conductivity of the substrate. Consequently, a conventional projector module suffers from a high thermal resistance that decreases an optical power output of the conventional projector module (e.g., due to a high VCSEL junction temperature associated with the VCSEL device of the conventional projector module).

Some implementations described herein provide an optical subassembly for an electro-optical device, such as a ToF device. The optical subassembly includes an IC driver chip and an RDL structure that is disposed on a surface of the IC driver chip. The optical subassembly further includes a VCSEL device disposed on a region of the surface of the RDL structure. Accordingly, by disposing the VCSEL device over the IC driver chip (e.g., instead of positioning the VCSEL device and the IC driver chip next to each other), the optical subassembly has a reduced size as compared to a substrate of a conventional projector module and, thus, a size (e.g., an XY footprint) of the electro-optical device is reduced as compared to a size of the conventional projector module. This enables the electro-optical device to be included in some user devices, such as smart phones.

Some implementations described herein provide an optical assembly for an electro-optical device. The optical assembly includes the optical subassembly (described herein), a substrate, a housing, and a plastic optical element, such as a plastic collimating lens. The plastic optical element is attached to the housing (e.g., over the VCSEL device of the optical subassembly) via one or more ultrasonic welds and/or one or more laser welds. Accordingly, by using a plastic optical element that is less likely to break (e.g., as compared to a glass optical element) and that is unlikely to fall off from the housing (e.g., because the plastic optical element is integrated into the housing via the one or more ultrasonic welds and/or the one or more laser welds), a PD does not need to be included in the optical subassembly to detect a failure of the plastic optical element. In this way, a size of the optical subassembly is additionally reduced and, thus, a size (e.g., an XY footprint) of the electro-optical device is additionally reduced as compared to a size of a conventional projector module.

In some implementations, the RDL structure of the optical subassembly includes one or more dielectric layers (e.g., each with a thickness that is less than or equal to 5 μm) that are thinner than a dielectric material typically included in a substrate of a conventional projector module. Accordingly, the one or more dielectric layers have a reduced effect on a thermal conductivity of the RDL structure. Additionally, in some implementations, the RDL structure includes a cavity and the VCSEL device is disposed on a region of the surface of the RDL structure that is within the cavity of the RDL structure. This reduces a number of dielectric layers through which heat generated by the VCSEL device has to pass in the RDL structure. The heat then dissipates to the IC driver chip, which has a high thermal conductivity (e.g., because the IC driver chip comprises silicon (Si) or another material with high thermal conductivity). Therefore, the electro-optical device has an improved thermal performance as compared to a conventional projector module, which causes the electro-optical device to have an increased optical power output as compared to the optical power output of the conventional projector module (e.g., due to a lower VCSEL junction temperature associated with the VCSEL device of the electro-optical device).

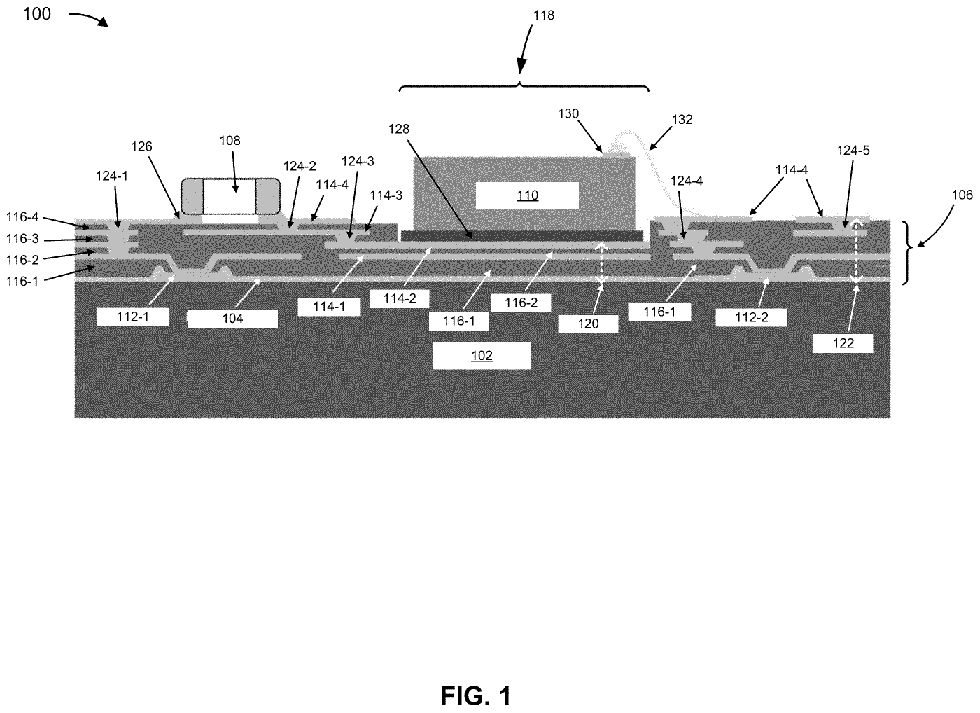

FIG. 1 is a diagram of an example optical subassembly 100 for an electro-optical device, such as a ToF device. FIG. 1 illustrates a side cut-away view of the optical subassembly 100. As shown in FIG. 1, the optical subassembly 100 may include an integrated circuit (IC) driver chip 102, a passivation layer 104, a redistribution layer (RDL) structure 106, a capacitor 108, and/or a VCSEL device 110.

The IC driver chip 102 may comprise silicon (Si), indium phosphide (InP), gallium arsenide (GaAs), and/or another similar material. The IC driver chip 102 may be configured to generate and provide an electric signal to the VCSEL device 110 (e.g., to cause the VCSEL device 110 to emit an output beam). The passivation layer 104 may include silicon nitride (Si₃N₄), silicon dioxide (SiO₂), and/or another passivation material. As shown in FIG. 1, the passivation layer may be disposed on at least a portion of a surface of the IC driver chip 102 (e.g., at least a portion of a top surface of the IC driver chip 102).

The RDL structure 106 may include a set of bond pads 112 (e.g., one or more bond pads 112, shown as bond pads 112-1 and 112-2 in FIG. 1), a set of metal layers 114 (e.g., one or more metal layers 114, shown as metal layers 114-1 through 114-4 in FIG. 1), and/or a set of dielectric layers 116 (e.g., one or more dielectric layers 116, shown as dielectric layers 116-1 through 116-4 in FIG. 1). As shown in FIG. 1, the RDL structure 106 may be disposed on at least a portion of the surface of the IC driver chip 102 (e.g., the top surface of the IC driver chip 102) and/or at least a portion of the surface of the passivation layer 104 (e.g., a top surface of the passivation layer 104).

In some implementations, the RDL structure 106 may include a cavity 118. For example, a portion of one or more metal layers 114, of the set of metal layers 114, and/or a portion of one or more dielectric layers 116, of the set of dielectric layers 116, may be removed (e.g., using an etch removal process), or may not be formed, to cause the RDL structure 106 to include the cavity 118. In this way, as shown in FIG. 1, a thickness 120 of a portion of the RDL structure 106 that is associated with the cavity 118 may be less than a thickness 122 of another portion of the RDL structure 106 that is not associated with the cavity 118.

In some implementations, the set of bond pads 112 of the RDL structure 106 may be disposed on respective regions of the surface of the IC driver chip 102 (e.g., respective regions of the top surface of the IC driver chip 102). For example, as shown in FIG. 1, the bond pad 112-1 is disposed on a region of the IC driver chip 102 that is not covered by the passivation layer 104. The set of bond pads 112 may be configured to provide an electric signal generated by the IC driver chip 102 to at least one metal layer 114 of the set of metal layers 114 (e.g., to cause the electric signal to be provided to the VCSEL device 110 to cause the VCSEL device 110 to emit an output beam).

Each of the set of metal layers 114 of the RDL structure 106 may comprise, for example, tungsten (W), a W alloy, copper (Cu), a Cu alloy, a CuW alloy, molybdenum (Mo), a Mo alloy, a WMo alloy, silver (Ag), and/or an Ag alloy. Each of the set of dielectric layers 116 of the RDL structure 106 may comprise, for example, polyimide, an Ajinomoto build-up film (ABF), and/or another dielectric material. In some implementations, a dielectric layer 116, of the set of dielectric layers 116, may be disposed between two different metal layers 114 of the set of metal layers 114. For example, as shown in FIG. 1, the dielectric layer 116-2 may be disposed between the metal layers 114-1 and 114-2. Additionally, or alternatively, a metal layer 114, of the set of metal layers 114, may be disposed between two different dielectric layers 116 of the set of dielectric layers 116. For example, as shown in FIG. 1, the metal layer 114-1 may be disposed between the dielectric layers 116-1 and 116-2.

The set of metal layers 114 and the set of dielectric layers 116 may be arranged in a particular order. In some implementations, the set of metal layers 114 and the set of dielectric layers 116 may be arranged in an alternating order, such as an (A/B)_{N} order, a (B/A)_{N} order, an (AB)_{N}A order, or a (B/A)_{N}B order (e.g., where A represents a metal layer 114, B represents a dielectric layer 116, and N≥1 and represents a number of times a pattern enclosed in parentheses is repeated). For example, as shown in FIG. 1, the set of metal layers 114 and the set of dielectric layers 116 are arranged in a (B/A)₄ alternating order, with a bottom surface of the RDL structure 106 comprising a dielectric layer 116 and a top surface of the RDL structure 106 comprising a metal layer 114.

In some implementations, the RDL structure 106 may include a set of conductive structures 124 (e.g., one or more conductive structures 124, shown as conductive structures 124-1 through 124-5 in FIG. 1). Each of the set of conductive structures 124 may comprise, for example, W, a W alloy, Cu, a Cu alloy, a CuW alloy, Mo, a Mo alloy, a WMo alloy, Ag, and/or an Ag alloy. Additionally, or alternatively, each of the set of conductive structures 124 may be configured to electrically connect two or more metal layers 114 of the set of metal layers 114. For example, as shown in FIG. 1, the conductive structure 124-1 is configured to electrically connect the metal layers 114-1, 114-2, 114-3, and 114-4. In some implementations, the set of conductive structures 124 may be configured to facilitate transmission of an electric signal generated by the IC driver chip 102 to the VCSEL device 110 via the set of metal layers 114 (e.g., to cause the VCSEL device 110 to emit an output beam).

The capacitor 108 may be disposed on a first region of a surface of the RDL structure 106 (e.g., a first region of a top surface of the RDL structure 106). In some implementations, the capacitor 108 may be electrically and/or structurally connected to the first region of the surface of the RDL structure via an attachment material 126, such as an epoxy (e.g., silver-epoxy (Ag-epoxy), sintered Ag-epoxy, or semi-sintered Ag-epoxy), a solder, and/or a similar material.

The VCSEL device 110 may be disposed on a second region of the surface of the RDL structure 106 (e.g., a second region of the top surface of the RDL structure 106). In some implementations, the VCSEL device 110 may be electrically and/or structurally connected to the second region of the surface of the RDL structure 106 via an attachment material 128, such as a conductive epoxy (e.g., sintered Ag-epoxy, semi-sintered Ag-epoxy, or Ag-epoxy), a solder, and/or a similar material. In some implementations, the second region may be associated with the cavity 118 of the RDL structure 106. For example, as shown in FIG. 1, the VCSEL device 110 may be disposed on a region of the top surface of the RDL structure 106 that is within the cavity 118 of the RDL structure 106. The VCSEL device 110 may include, for example, a short-wave infrared (SWIR) VCSEL device, an oxide confined VCSEL device, an implant confined VCSEL device, a mesa confined VCSEL device, a top emitting VCSEL device, or a bottom emitting VCSEL device. In some implementations, the VCSEL device 110 may be configured to emit an output beam (e.g., an output laser beam).

In some implementations, a first metal layer 114, of the set of metal layers 114, may be configured as a ground for the VCSEL device 110. For example, as shown in FIG. 1, the metal layer 114-1 may be configured as the ground for the VCSEL device 110 and may be disposed between the passivation layer 104 and a bottom surface of the VCSEL device 110. In some implementations, a second metal layer 114, of the set of metal layers 114, may be configured as a cathode or an anode for the VCSEL device 110. For example, as shown in FIG. 1, the metal layer 114-2 may be configured as the cathode for the VCSEL device 110 and may be disposed between the metal layer 114-1 and the bottom surface of the VCSEL device 110. Additionally, or alternatively, as further shown in FIG. 1, the VCSEL device 110 may be disposed on the metal layer 114-2 within the cavity of the RDL structure 106 (and electrically and/or structurally connected to the metal layer 114-2 via the attachment material 128).

In some implementations, a third metal layer 114, of the set of metal layers 114, may be located at one or more portions of the top surface of the RDL structure 106. For example, as shown in FIG. 1, the metal layer 114-4 may be located at one or more portions of the top surface of the RDL structure 106. In some implementations, the third metal layer 114 may be electrically connected to the VCSEL device 110 and/or the capacitor 108. For example, as shown in FIG. 1, the metal layer 114-4 may be electrically connected to a bondpad 130 of the VCSEL device 110 via a wire bond 132 and/or may be connected to the capacitor 108 via the attachment material 126.

As indicated above, FIG. 1 is provided as an example. Other examples may differ from what is described with regard to FIG. 1. In practice, the optical subassembly 100 may include additional layers and/or elements, fewer layers and/or elements, different layers and/or elements, or differently arranged layers and/or elements than those shown in FIG. 1.

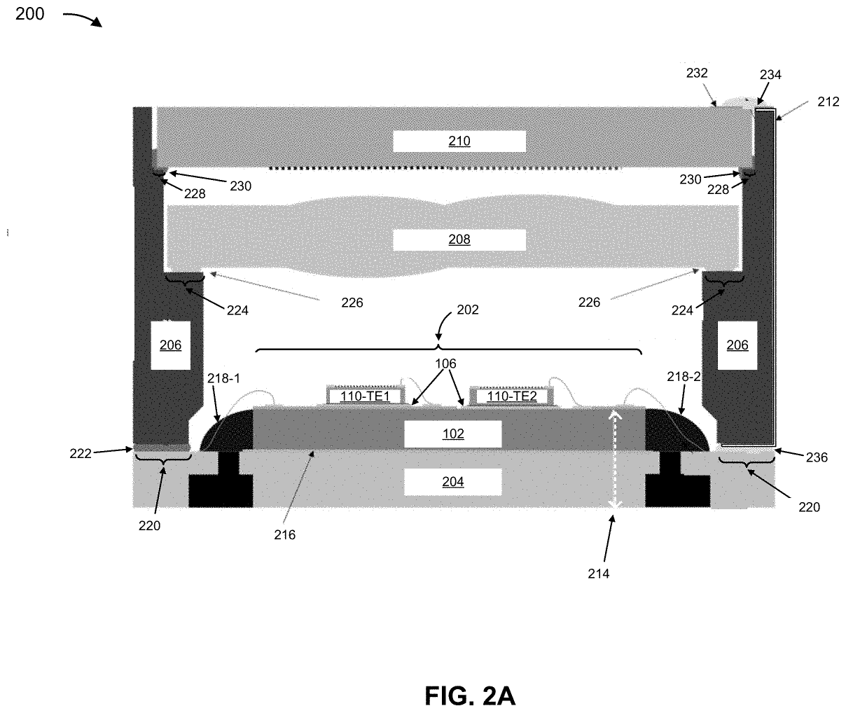

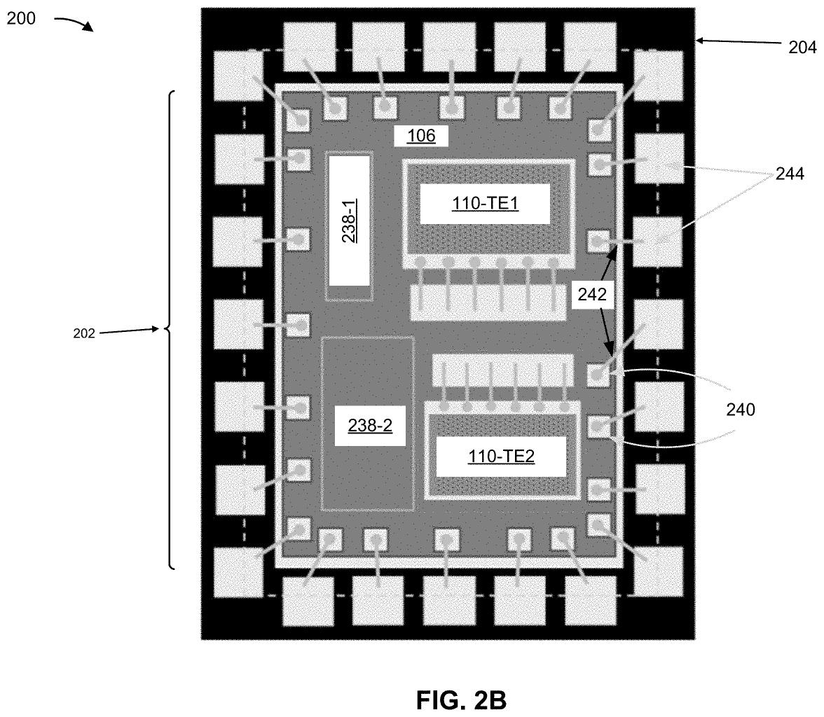

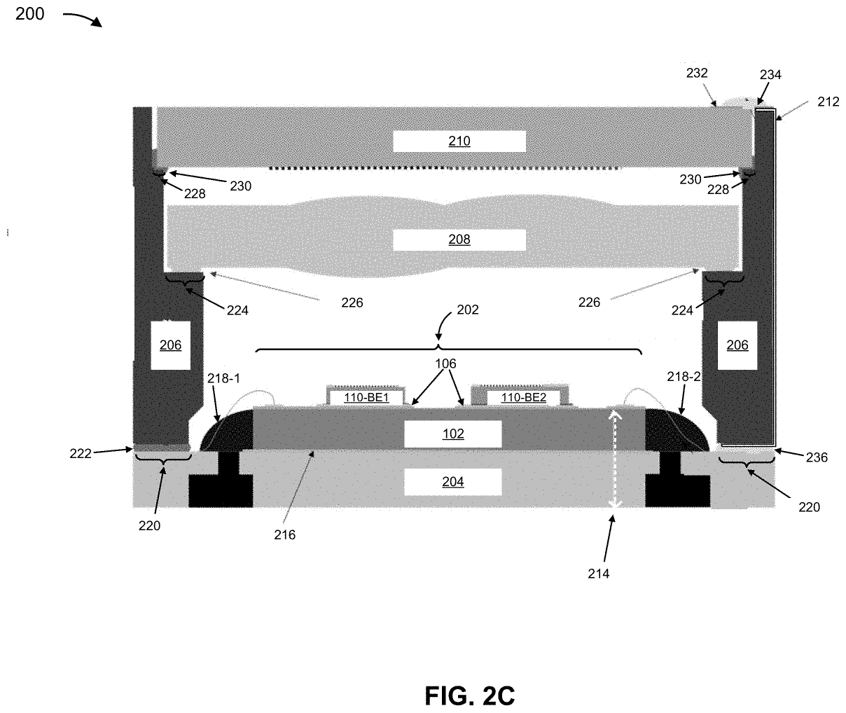

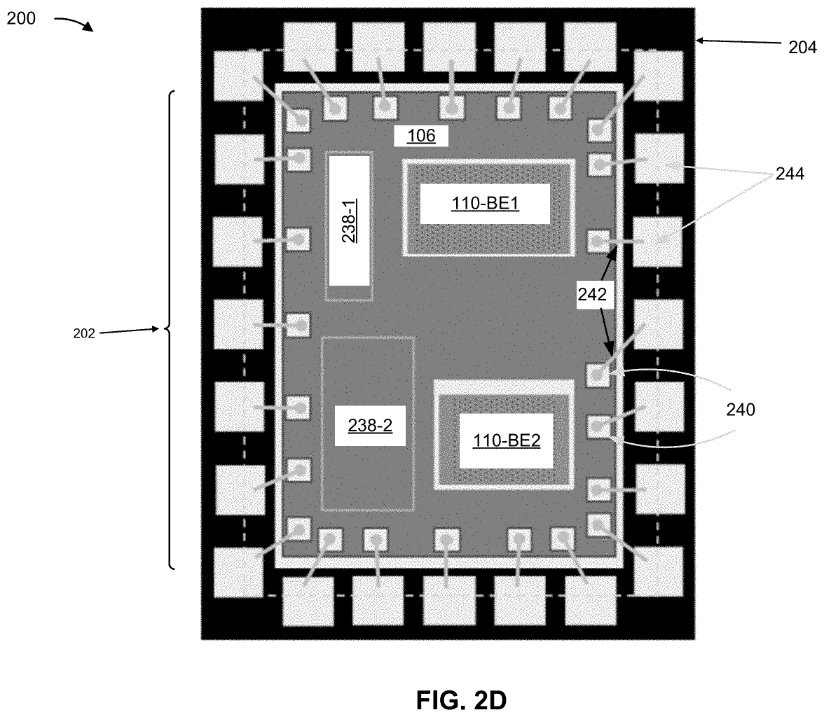

FIGS. 2A-2D are diagrams of an example optical assembly 200 for an electro-optical device, such as a ToF device. FIG. 2A illustrates a side cut-away view of the optical assembly 200. As shown in FIG. 2A, the optical assembly 200 may include an optical subassembly 202, a substrate 204, a housing 206, a first optical element 208, a second optical element 210, and/or a conductive trace 212.

The optical subassembly 202 may be the same as, or similar to, the optical subassembly 100 described herein in relation to FIG. 1. For example, as shown in FIG. 2A, the optical subassembly 202 may include an IC driver chip 102, at least one RDL structure 106, and/or at least one VCSEL device 110. Notably, as shown in FIG. 2A, the at least one VCSEL device 110 may include at least one top emitting VCSEL device (e.g., shown as top emitting VCSEL devices 110-TE1 and 110-TE2).

The substrate 204 may be a lead frame, such as Cu-based molded lead frame, or Cu alloy-based molded lead frame, or metal alloy with thermal conductivity greater than or equal to a thermal conductivity threshold (e.g., 15 watts W/mK). In some implementations, the optical subassembly 202 may be disposed on a region of a surface of the substrate 204 (e.g., a region of a top surface of the substrate 204). For example, as shown in FIG. 2A, the optical subassembly 202 may be disposed on a central region of the top surface of the substrate 204. In some implementations, a thickness 214 of the IC driver chip 102 and the substrate 204 may be within a range of 150 to 1100 micrometers (μm) (e.g., greater than or equal to 150 μm and less than or equal to 1100 μm). For example, a thickness of the IC driver chip 102 may be within a range of 100 to 600 μm and a thickness of the substrate 204 may be within a range of 50 to 500 μm.

In some implementations, the optical subassembly 202 may be electrically and/or structurally connected to the region of the surface of the substrate 204 via an attachment material 216, such as an epoxy (e.g., sintered Ag-epoxy, semi-sintered Ag-epoxy, or Ag-epoxy), a solder, and/or a similar material. In some implementations, one or more encapsulations 218 (shown as encapsulations 218-1 and 218-2) may be disposed on respective portions of the optical subassembly 202 and/or the substrate 204. For example, as shown in FIG. 2A, the encapsulation 218-1 may be disposed on a left surface of the optical subassembly 202 (e.g., a left surface of the IC driver chip 102) and a left portion of the top surface of the substrate 204. Each encapsulation 218 may be configured to provide structural support to the optical subassembly 202 and/or the substrate 204 and may be connected to the optical subassembly 202 and/or the substrate 204 via an attachment material (not shown in FIG. 2), such as an epoxy (e.g., an insulative epoxy), a solder, or a similar material. Additionally or alternatively, the encapsulation 218 may be configured around all or part of a periphery of the optical subassembly 202.

The housing 206 may comprise a polymer material, a plastic material, and/or a similar material and may be disposed on the substrate 204. For example, as shown in FIG. 2A, the housing 206 may be disposed on at least a portion of a perimeter region 220 of the substrate 204. In some implementations, at least a portion of the housing 206 may be structurally connected to the substrate 204 via an attachment material 222, such as an epoxy (e.g., an insulative epoxy), a solder, and/or a similar material.

In some implementations, the housing 206 may include at least one first support component 224 that is configured to hold the first optical element 208. For example, as shown in FIG. 2A, the housing 206 may include at least one first support component 224 that comprises a “step” or a “ledge” on which the first optical element 208 is disposed. The first optical element 208 may include a collimating lens and may comprise a polymer material, a plastic material, and/or a similar material. In some implementations, the first optical element 208 may be structurally connected to a first support component 224 via one or more welds 226, such as one or more ultrasonic welds, one or more laser welds, or one or more similar welds.

In some implementations, the housing 206 may include at least one second support component 228 that is configured to hold the second optical element 210. For example, as shown in FIG. 2A, the housing 206 may include at least one second support component 228 that comprises a “step” or a “ledge” on which the second optical element 210 is disposed. The second optical element 210 may include a diffractive optical element (DOE) and/or a diffuser and may comprise a glass material. In some implementations, the second optical element 210 may be structurally connected to the at least one second support component 228 via an attachment material 230, such as an epoxy (e.g., an insulative epoxy), a solder, and/or a similar material.

In some implementations, the housing 206 may include a conductive path 232 associated with the second optical element 210 (e.g., to facilitate detection of damage to the second optical element 210). The conductive path 232 may comprise, for example, indium tin oxide (ITO). As further shown in FIG. 2A, an attachment material 234 may be configured to structurally connect the conductive path 232 and/or the second optical element 210 to the housing 206. Additionally, or alternatively, the attachment material 234 may be configured to electrically connect the conductive path 232 to the conductive trace 212, which may be disposed on a surface of the housing 206. For example, the attachment material 234 may include a conductive epoxy (e.g., sintered Ag-epoxy, semi-sintered Ag-epoxy, or Ag-epoxy), a solder, and/or a similar material. The conductive trace 212 may comprise a metal, such as Cu, nickel (Ni), and/or gold (Au), among other examples.

As further shown in FIG. 2A, an attachment material 236 may be configured to structurally connect the conductive trace 212 to the substrate 204. Additionally, or alternatively, the attachment material 236 may be configured to electrically connect the conductive trace 212 to the substrate 204. For example, the attachment material 236 may include a conductive epoxy (e.g., sintered Ag-epoxy, semi-sintered Ag-epoxy, or Ag-epoxy), a solder, and/or a similar material. Accordingly, the conductive trace 212 may be configured to provide an electrical connection between the optical subassembly 202 (e.g., via the substrate 204) and the conductive path 232 (e.g., via the attachment material 234 and the attachment material 236).

FIG. 2B illustrates a top-down view of the optical assembly 200 (without the housing 206, the first optical element 208, the second optical element 210, and the conductive trace 212). As shown in FIG. 2B, the optical assembly 200 may include the optical subassembly 202 disposed on the substrate 204. The optical subassembly 202 may include the RDL structure 106 (e.g., that is disposed on the IC driver chip 102), the at least one VCSEL device 110 (e.g., shown as top emitting VCSEL devices 110-TE1 and 110-1E2), a first electrical element 238-1 (e.g., a first capacitor 108), and/or a second electrical element 238-2 (e.g., a second capacitor 108, such as an equivalent series inductance (ESL) capacitor). As further shown in FIG. 2B, the optical subassembly 202 may include a set of bondpads 240 (e.g., one or more bondpads 240) that are connected via wire bonds 242 (e.g., one or more wire bonds 242) to a set of bondpads 244 (e.g., one or more bondpads 244) of the substrate 204.

FIG. 2C illustrates a side cut-away view of an alternative configuration of the optical assembly 200. As shown in FIG. 2C, the optical assembly 200 may include the optical subassembly 202, the substrate 204, the housing 206, the first optical element 208, the second optical element 210, and/or the conductive trace 212 (e.g., as described herein in relation to FIG. 2A). Further, the optical subassembly 202 may include an IC driver chip 102, at least one RDL structure 106, and/or at least one VCSEL device 110 (e.g., as described herein in relation to FIG. 2A). Notably, as shown in FIG. 2C, the at least one VCSEL device 110 may include at least one bottom emitting VCSEL device (e.g., shown as bottom emitting VCSEL devices 110-BE1 and 110-BE2).

FIG. 2D illustrates a top-down view of the alternative configuration of the optical assembly 200 (without the housing 206, the first optical element 208, the second optical element 210, and the conductive trace 212). As shown in FIG. 2D, the optical assembly 200 may include the optical subassembly 202 disposed on the substrate 204. The subassembly 202 may include the RDL structure 106 (e.g., that is disposed on the IC driver chip 102), the at least one VCSEL device 110 (e.g., shown as bottom emitting VCSEL devices 110-BE1 and 110-BE2), the first electrical element 238-1 (e.g., a first capacitor 108), and/or the second electrical element 238-2 (e.g., a second capacitor 108, such as an equivalent series inductance capacitor). As further shown in FIG. 2D, the subassembly 202 may include the set of bondpads 240 (e.g., one or more bondpads 240) that are connected via the wire bonds 242 (e.g., one or more wire bonds 242) to the set of bondpads 244 (e.g., one or more bondpads 244) of the substrate 204.

As indicated above, FIGS. 2A-2D are provided as an example. Other examples may differ from what is described with regard to FIGS. 2A-2D. In practice, the optical assembly 200 may include additional layers and/or elements, fewer layers and/or elements, different layers and/or elements, or differently arranged layers and/or elements than those shown in FIGS. 2A-2D.

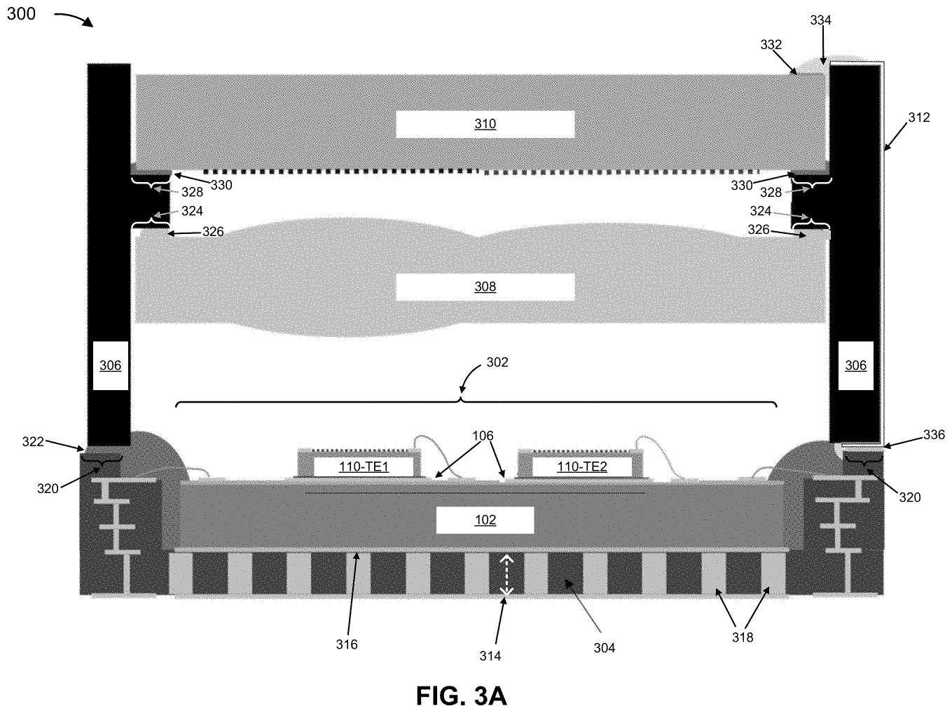

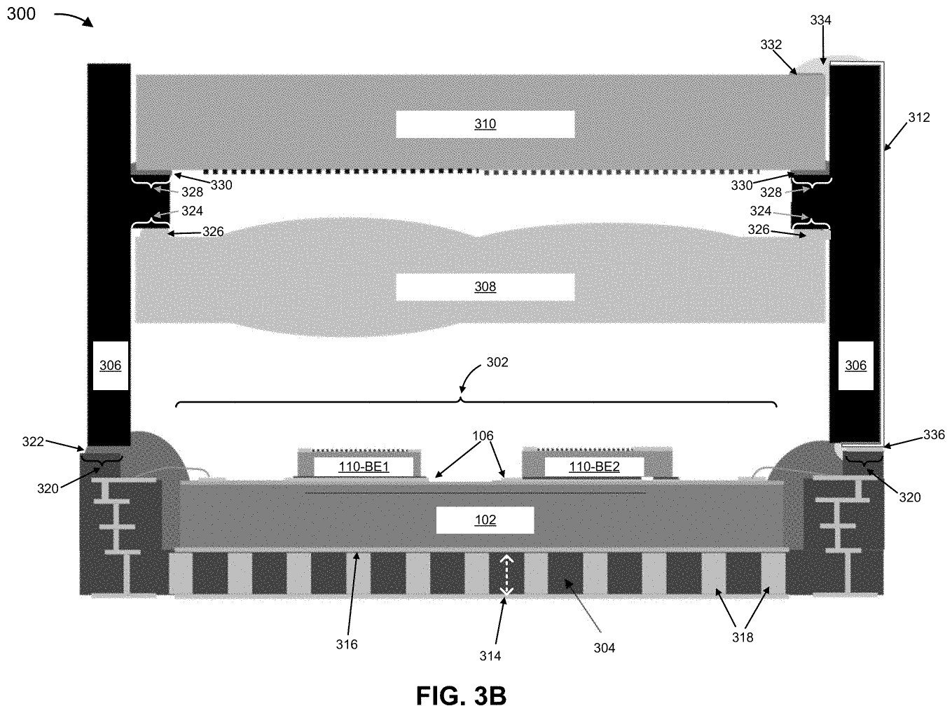

FIGS. 3A-3B are diagrams of an example optical assembly 300 for an electro-optical device, such as a ToF device. FIG. 3A illustrates a side cut-away view of the optical assembly 300. As shown in FIG. 3A, the optical assembly 300 may include an optical subassembly 302, a substrate 304, a housing 306, a first optical element 308, a second optical element 310, and/or a conductive trace 312.

The optical subassembly 302 may be the same as, or similar to, the optical subassembly 100 described herein in relation to FIG. 1 and/or the optical subassembly 202 described herein in relation to FIG. 2. For example, as shown in FIG. 3A, the optical subassembly 302 may include an IC driver chip 102, at least one RDL structure 106, and/or at least one VCSEL device 110. Notably, as shown in FIG. 3A, the at least one VCSEL device 110 may include at least one top emitting VCSEL device (e.g., shown as top emitting VCSEL devices 110-TE1 and 110-TE2).

The substrate 304 may be an open-cavity ceramic substrate, such as an open-cavity high temperature co-fired ceramic (HTCC) substrate, an open-cavity low temperature co-fired ceramic (LTCC) substrate, or a similar substrate. In some implementations, the open-cavity ceramic substrate may comprise aluminum oxide (Al₂O₃), aluminum nitride (AlN), or a similar material. In some implementations, the optical subassembly 302 may be disposed on a region of a surface of the substrate 304 (e.g., a region of a top surface of the substrate 304). For example, as shown in FIG. 3A, the optical subassembly 302 may be disposed on a central region of the top surface of the substrate 304. In some implementations, a thickness 314 of a portion of the substrate 304 that is associated with a cavity of the substrate may be within a range of 50 to 500 micrometers (μm) (e.g., greater than or equal to 50 μm and less than or equal to 500 μm).

In some implementations, the optical subassembly 302 may be electrically and/or structurally connected to the region of the surface of the substrate 304 via an attachment material 316, such as an epoxy (e.g., sintered Ag-epoxy, semi-sintered Ag-epoxy, or Ag-epoxy), a solder, and/or a similar material. In some implementations, the substrate 304 may include one or more vias 318. The one or more vias 318 may be empty (e.g., hollow) or filled with a metal, such as W, a W alloy, Cu, a Cu alloy, a CuW alloy, Mo, a Mo alloy, a WMo alloy, Ag, and/or an Ag alloy, among other examples.

The housing 306 may comprise a polymer material, a plastic material, and/or a similar material and may be disposed on the substrate 304. For example, as shown in FIG. 3A, the housing 306 may be disposed on at least a portion of a perimeter region 320 of the substrate 304. In some implementations, at least a portion of the housing 306 may be structurally connected to the substrate 304 via an attachment material 322, such as an epoxy (e.g., an insulative epoxy), a solder, and/or a similar material.

In some implementations, the housing 306 may include at least one first support component 324 that is configured to hold the first optical element 308. For example, as shown in FIG. 3A, the housing 306 may include at least one first support component 324 that comprises a bottom surface of a “cantilever” or a “ledge” on which the first optical element 308 is disposed. The first optical element 308 may include a collimating lens and may comprise a polymer material, a plastic material, and/or a similar material. In some implementations, the first optical element 308 may be structurally connected to a first support component 324 via one or more welds 326, such as one or more ultrasonic welds, one or more laser welds, or one or more similar welds.

In some implementations, the housing 306 may include at least one second support component 328 that is configured to hold the second optical element 310. For example, as shown in FIG. 3A, the housing 306 may include at least one second support component 328 that comprises a top surface of a “cantilever” or a “ledge” on which the second optical element 310 is disposed. The second optical element 310 may include a DOE and/or a diffuser and may comprise a glass material. In some implementations, the second optical element 310 may be structurally connected to the at least one second support component 328 via an attachment material 330, such as an epoxy (e.g., an insulative epoxy), a solder, and/or a similar material.

In some implementations, the housing 306 may include a conductive path 332 associated with the second optical element 310 (e.g., to facilitate detection of damage to the second optical element 310). The conductive path 332 may comprise, for example, ITO. As further shown in FIG. 3A, an attachment material 334 may be configured to structurally connect the conductive path 332 and/or the second optical element 310 to the housing 306. Additionally, or alternatively, the attachment material 334 may be configured to electrically connect the conductive path 332 to the conductive trace 312, which may be disposed on a surface of the housing 306. For example, the attachment material 334 may include an epoxy (e.g., sintered Ag-epoxy, semi-sintered Ag-epoxy, or Ag-epoxy), a solder, and/or a similar material. The conductive trace 312 may comprise a metal, such as Cu, nickel (Ni), and/or gold (Au), among other examples.

As further shown in FIG. 3A, an attachment material 336 may be configured to structurally connect the conductive trace 312 to the substrate 304. Additionally, or alternatively, the attachment material 336 may be configured to electrically connect the conductive trace 312 to the substrate 304. For example, the attachment material 336 may include an epoxy (e.g., sintered Ag-epoxy, semi-sintered Ag-epoxy, or Ag-epoxy), a solder, and/or a similar material. Accordingly, the conductive trace 312 may be configured to provide an electrical connection between the optical subassembly 302 (e.g., via the substrate 304) and the conductive path 332 (e.g., via the attachment material 334 and the attachment material 336).

FIG. 3B illustrates a side cut-away view of an alternative configuration of the optical assembly 300. As shown in FIG. 3B, the optical assembly 300 may include the optical subassembly 302, the substrate 304, the housing 306, the first optical element 308, the second optical element 310, and/or the conductive trace 312 (e.g., as described herein in relation to FIG. 3A). Further, the optical subassembly 302 may include an IC driver chip 102, at least one RDL structure 106, and/or at least one VCSEL device 110 (e.g., as described herein in relation to FIG. 3A). Notably, as shown in FIG. 3B, the at least one VCSEL device 110 may include at least one bottom emitting VCSEL device (e.g., shown as bottom emitting VCSEL devices 110-BE1 and 110-BE2).

As indicated above, FIGS. 3A-3B are provided as an example. Other examples may differ from what is described with regard to FIGS. 3A-3B. In practice, the optical assembly 300 may include additional layers and/or elements, fewer layers and/or elements, different layers and/or elements, or differently arranged layers and/or elements than those shown in FIGS. 3A-3B.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “bottom,” “above,” “upper,” “top,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. And, comprising:
an integrated circuit (IC) driver chip;
a redistribution layer (RDL) structure that is disposed on a surface of the IC driver chip,
wherein the RDL structure includes a cavity; and
a vertical cavity surface emitting laser (VCSEL) device disposed on a region of the surface of the RDL structure that is within the cavity of the RDL structure.

2. The optical subassembly of claim 1, wherein the IC driver chip comprises at least one of:
silicon (Si);
indium phosphide (InP);
or gallium arsenide (GaAs).

3. The optical subassembly of claim 1, wherein the VCSEL device comprises:
a short-wave infrared (SWIR) VCSEL device;
an oxide confined VCSEL device;
an implant confined VCSEL device;
a mesa confined VCSEL device;
a top emitting VCSEL device; or
a bottom emitting VCSEL device.

4. The optical subassembly of claim 1, further comprising a passivation layer,
wherein the passivation layer is disposed on at least a portion of the surface of the IC driver chip.

5. The optical subassembly of claim 1, wherein the RDL structure includes one or more bond pads,
wherein the one or more bond pads are disposed on respective regions of the surface of the IC driver chip.

6. The optical subassembly of claim 1, wherein the RDL structure includes one or more metal layers and d.

7. The optical subassembly of claim 1, wherein the RDL structure includes one or more metal layers and one or more dielectric layers, and
wherein the one or more metal layers and the one or more dielectric layers are arranged in an alternating order.

8. The optical subassembly of claim 1, wherein the RDL structure includes one or more metal layers, and wherein:
a particular metal layer, of the one or more metal layers, is configured as a ground for the VCSEL device.

9. The optical subassembly of claim 1, wherein the RDL structure includes one or more metal layers, and wherein:
a particular metal layer, of the one or more metal layers, is configured as a cathode for the VCSEL device.

10. The optical subassembly of claim 1, further comprising a capacitor,
wherein the capacitor is disposed on another region of the surface of the RDL structure that is not within the cavity of the RDL structure.

11. An optical assembly, comprising:
a substrate;
an optical subassembly that is disposed on a region of a surface of the substrate;
a housing that is disposed on another region of the surface of the substrate;
a first optical element that is disposed on a first support component of the housing; and
a second optical element that is disposed on a second support component of the housing,
wherein the optical subassembly comprises:
an integrated circuit (IC) driver chip,
a redistribution layer (RDL) structure that is disposed on a surface of the IC driver chip,
wherein the RDL structure includes a cavity, and
a vertical cavity surface emitting laser (VCSEL) device disposed on a region of the surface of the RDL structure that is within the cavity of the RDL structure.

12. The optical assembly of claim 11, wherein the substrate is a lead frame or an open-cavity ceramic substrate.

13. The optical assembly of claim 11, wherein the first optical element is a plastic collimating lens and is attached to the first support component via at least one of one or more ultrasonic welds or one or more laser welds.

14. The optical assembly of claim 11, wherein the second optical element is at least one of a diffractive optical element (DOE) or a diffuser and is attached to the second support component via an attachment material.

15. The optical assembly of claim 11, further comprising a conductive trace, wherein:
the conductive trace is disposed on a surface of the housing and is electrically connected to the optical subassembly and a conductive path associated with at least one of the first optical element or the second optical element.

16. The optical assembly of claim 11, wherein the optical subassembly is connected to the substrate via an attachment material that comprises at least one of:
silver-epoxy (Ag-epoxy);
sintered Ag-epoxy;
semi-sintered Ag-epoxy; or
a solder.

17. An optical assembly, comprising:
a substrate; and
an optical subassembly that is disposed on a region of a surface of the substrate,
wherein the optical subassembly comprises:
an integrated circuit (IC) driver chip,
a redistribution layer (RDL) structure that is disposed on a surface of the IC driver chip,
wherein the RDL structure includes a cavity, and
a vertical cavity surface emitting laser (VCSEL) device disposed on a region of the surface of the RDL structure that is within the cavity of the RDL structure.

18. The optical assembly of claim 17, wherein the substrate is a lead frame or an open-cavity ceramic substrate.

19. The optical assembly of claim 17, further comprising a housing and a plastic optical element, wherein:
the plastic optical element is attached to the housing via at least one of one or more ultrasonic welds or one or more laser welds.

20. The optical assembly of claim 17, further comprising a housing and a glass optical element, wherein:
the glass optical element is attached to the housing via an attachment material.
